(19) United States
(12) Patent Application Publication
(10) Pub. No.: US 2018/0068870 A1
(43) Pub. Date: Mar. 8, 2018

(54) ELECTRONIC PACKAGE AND METHOD FOR FABRICATING THE SAME

(71) Applicant: Siliconware Precision Industries Co., Ltd., Taichung City (TW)

(72) Inventors: Kuo-Ching Tsai, Taichung (TW); Jau-En Liang, Taichung City (TW); Hsin-Long Chen, Taichung City (TW)

(21) Appl. No.: 15/696,389

(22) Filed: Sep. 6, 2017

Related U.S. Application Data
(60) Provisional application No. 62/384,468, filed on Sep. 7, 2016.
(60) Provisional application No. 62/414,221, filed on Oct. 28, 2016.

(30) Foreign Application Priority Data
Jun. 3, 2017 (TW) 106118407

(51) Int. Cl. H01L 21/48; H01L 25/065; H01L 23/00; H01L 21/56

(52) U.S. Cl. CPC H01L 21/4864; H01L 25/0657; H01L 24/29; H01L 24/13; H01L 2224/13147; H01L 24/83; H01L 2225/06517; H01L 2225/0652; H01L 21/563

(57) ABSTRACT

The present disclosure provides an electronic package and a method for fabricating the same. The method including: connecting a first carrier structure with an electronic component via a bonding layer formed thereon; stacking the first carrier structure on a second carrier structure via a plurality of conductive elements; and electrically connecting the electronic component to the second carrier structure to thereby maintain and secure the distance between the first and second carrier structures.

### BACKGROUND

### 1. Technical Field

The present disclosure relates to package structures, and, more particularly, to an electronic package and a method for fabricating the same.

### 2. Description of Related Art

With the rapid development of portable electronic products in the recent years, products are trending toward higher density, higher performance, more compact and lighter. In order to accommodate the demands for smaller form factors and higher density, the semiconductor industry has developed an array of package-on-package (PoP) technologies.

As shown in FIG. 1, a method for fabricating a traditional PoP semiconductor package 1 involves bonding a semiconductor chip 11 onto a first package substrate 10 via a plurality of solder bumps 110 in a flip-chip manner, the solder bumps 110 are reflowed, and a first flux cleaning operation is performed. Then, an underfill 14 is applied to encapsulate the solder bumps 110. Thereafter, a second package substrate 12 is supported by and electrically connected to the first package substrate 10 via a plurality of conductive elements 18 that contain solder materials. The conductive elements 18 are reflowed and a second flux cleaning operation is performed. Finally, an encapsulant 13 is formed between the first package substrate 10 and the second package substrate 12 to encapsulate these conductive elements 18.

However, in the traditional semiconductor package 1, the distance between the first package substrate 10 and the second package substrate 12 is controlled by the conductive elements 18. The tolerances of the volume and height of the conductive elements 18 after reflow are large, which not only result in flawed contacts that lead to poor electrical connections, but poor coplanarity of the grid array formed by these conductive elements 18, which leads to imbalanced contact stress and sloped coupling between the first and the second package substrates 10 and 12, or even contact offset.

Furthermore, the fabrication process of the traditional semiconductor package 1 is rather complex (e.g., requiring two flux cleaning procedures) and the production cost is higher.

Therefore, there is a need for a solution that addresses the aforementioned issues in the prior art.

### SUMMARY

In view of the aforementioned shortcomings of the prior art, the present disclosure provides an electronic package, which may include: a first carrier structure; an electronic component provided on the first carrier structure via a bonding layer; a second carrier structure stacked on the first carrier structure via a plurality of conductive elements and electrically connected with the electronic component; and a covering layer formed between the first carrier structure and the second carrier structure and covering the electronic component and the conductive elements.

The present disclosure further provides a method for fabricating an electronic package, which includes: bonding an electronic component onto a first carrier structure via a bonding layer; stacking the first carrier structure on a second carrier structure via a plurality of conductive elements, and electrically connecting the electronic component and the second carrier structure; and forming between the first carrier structure and the second carrier structure a covering layer that covers the electronic component and the conductive elements.

In an embodiment, the method further comprises: forming the conductive elements on the first carrier structure; forming the covering layer on the first carrier structure to cover the electronic component and the conductive elements in a way that portions of surfaces of the conductive elements are exposed from the covering layer; and stacking the first carrier structure on the second carrier structure via the conductive elements with the covering layer formed between the first carrier structure and the second carrier structure.

In an embodiment, the method further includes: disposing the conductive elements on the first carrier structure; stacking the first carrier structure on the second carrier structure via the conductive elements; and forming between the first carrier structure and the second carrier structure the covering layer, which covers the electronic component and the conductive elements.

In an embodiment, the method may further include performing a flux cleaning operation after stacking the first carrier structure on the second carrier structure via the plurality of conductive elements.

In an embodiment, the electronic component is electrically connected with the second carrier structure via conductive bumps.

In an embodiment, the covering layer further covers the conductive bumps.

In an embodiment, the bonding layer is made of an adhesive material, a film or a heat dissipating material.

In an embodiment, the conductive elements include metal bumps and conductive materials covering the metal bumps.

In an embodiment, a gap may be formed between the covering layer and the second carrier structure. In another embodiment, portions of surfaces of the conductive elements may protrude from a surface of the covering layer. In yet another embodiment, an insulating layer may be further formed in the gap for covering the conductive elements. In still another embodiment, the insulating layer and the covering layer can be disposed in the same area. In further another embodiment, the electronic component may include an active face flush with a surface of the covering layer and a non-active face opposite to the active face and bonded to the bonding layer.

It can be seen from the above that in an electronic package and a method for fabricating the same according to the present disclosure, the electronic component is bonded onto the first carrier structure via the bonding layer, and thus the distance between the first carrier structure and the second carrier structure can be fixed. Compared to the prior art, contacts formed by the conductive elements after the conductive elements are reflowed according to the present disclosure, are able to maintain good electrical connections, and good coplanarity of the grid array formed by the conductive elements can be achieved, resulting in balanced contact stress and no sloped coupling between the first and second carrier structures, thereby preventing contact offset.

Moreover, the method for fabricating an electronic package according to the present disclosure requires only one flux cleaning process, which reduces the number of flux cleaning processes, thereby simplifying the manufacturing processes, reducing production cost and increasing product yield.

### BRIEF DESCRIPTION OF THE DRAWINGS

FIG. 1 is a cross-sectional diagram depicting a traditional package-on-package (PoP) semiconductor package;

FIGS. 2A to 2E are cross-sectional diagrams depicting a method for fabricating an electronic package in accordance with an embodiment of the present disclosure; and

FIGS. 3A and 3B are cross-sectional diagrams depicting the method for fabricating an electronic package in accordance with another embodiment of the present disclosure.

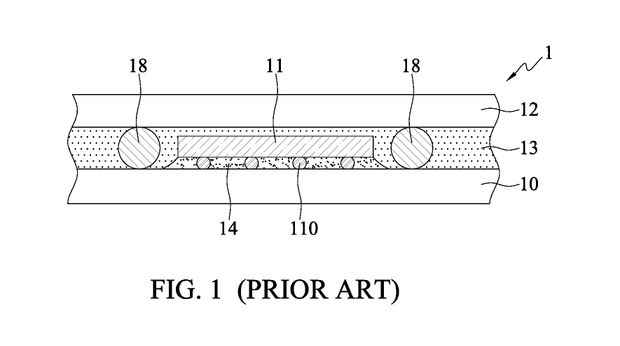

### DETAILED DESCRIPTION OF THE EMBODIMENTS

The present disclosure is described by the following specific embodiments. Those with ordinary skills in the arts can readily understand other advantages and functions of the present disclosure after reading the disclosure of this specification. The present disclosure may also be practiced or applied with other different implementations. Based on different contexts and applications, the various details in this specification can be modified and changed without departing from the spirit of the present disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range covered by the technical contents disclosed herein. Meanwhile, terms, such as “above”, “first”, “second”, “one”, “a”, “an”, and the like, are for illustrative purposes only, and are not meant to limit the range implementable by the present disclosure. Any changes or adjustments made to their relative relationships, without modifying the substantial technical contents, are also to be construed as within the range implementable by the present disclosure.

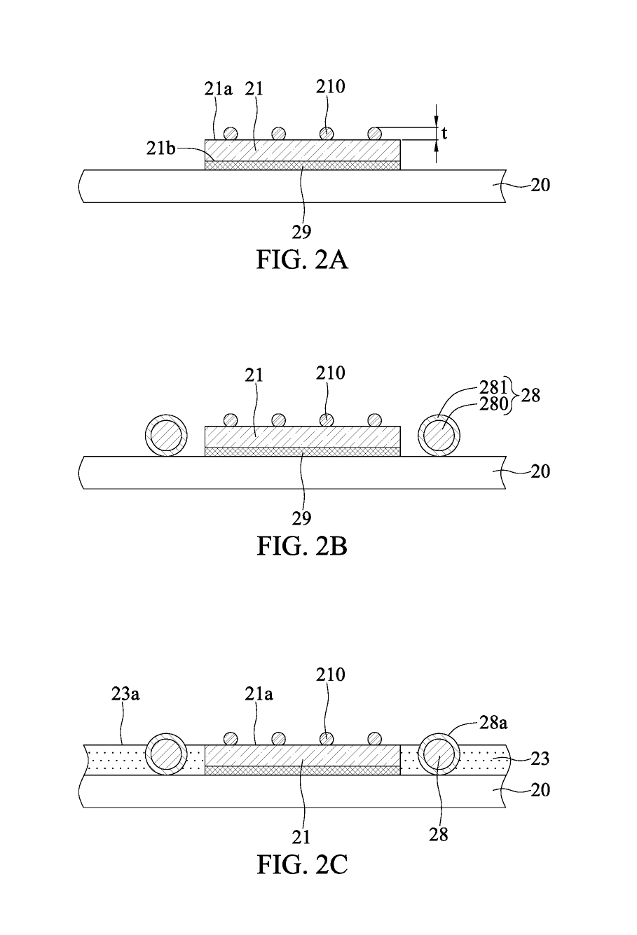

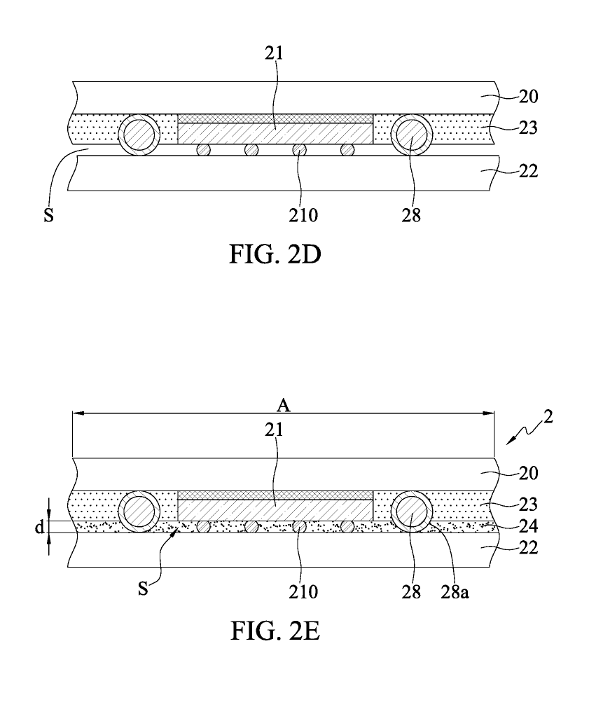

FIGS. 2A to 2E are cross-sectional diagrams depicting a method for fabricating an electronic package 2 in accordance with an embodiment of the present disclosure.

As shown in FIG. 2A, at least one electronic component 21 is disposed on a first carrier structure 20 via a bonding layer 29, such as an adhesive material, a film or a heat dissipating material.

In an embodiment, the first carrier structure 20 can be, for example, a substrate with a core layer and a circuit structure, or a coreless circuit structure, which forms a circuit layer on a dielectric material, such as a fan-out redistribution layer (RDL). It can be appreciated that the first carrier structure 20 can also be other types of carrier for carrying an electronic component (e.g., a chip), such as a lead frame, a silicon interposer, and the present disclosure is not so limited.

Moreover, the electronic component 21 can be an active element, a passive element or a combination of the two. The active element can be, for example, a semiconductor chip. The passive element can be, for example, a resistor, a capacitor or an inductor. In an embodiment, the electronic component 21 can be a semiconductor chip having an active face 21a and a non-active face 21b opposite to the active face 21a. A plurality of conductive bumps 210 (e.g., solder materials) are provided on the active face 21a. The non-active face 21b is bonded to a bonding layer 29.

As shown in FIG. 2B, a plurality of conductive elements 28 are disposed on the first carrier structure 20.

In an embodiment, the conductive elements 28 are solder balls with copper cores, including metal bumps 280 and conductive materials 281 surrounding the metal bumps 280. In other words, the metal bumps 280 are copper balls, and the conductive materials 281 are solder materials, such as nickel tin, tin lead or tin silver. It can be appreciated that there are numerous types of conductive elements 28, for example, the conductive elements 28 may include only copper balls or solder bumps. The present disclosure is not so limited.

As shown in FIG. 2C, a covering layer 23 is formed on the first carrier structure 20 and covers the electronic component 21 and the conductive elements 28 in such a way that portions of the surfaces of the conductive elements 28 and the conductive bumps 210 are exposed from the covering layer 23.

In an embodiment, the covering layer 23 can be formed of polyimide (PI), a dry film, an epoxy resin or a molding compound, but the present disclosure is not so limited.

In an embodiment, a surface 23a of the covering layer 23 is flush with the active face 21a of the electronic component 21.

In an embodiment, the conductive bumps 210 completely protrude from the surface 23a of the covering layer 23, while only ends 28a of the conductive elements 28 protrude from the surface 23a of the covering layer 23. In another embodiment, the conductive bumps 210 can be partially exposed from the covering layer 23.

As shown in FIG. 2D, the first carrier structure 20 is bonded with onto a second carrier structure 22 via the conductive elements 28, so that the first carrier structure 20 is stacked on top of the second carrier structure 22, and a gap S exists between the second carrier structure 22 and the covering layer 23.

In an embodiment, the second carrier structure 22 can be, for example, a substrate with a core layer and a circuit structure, or a coreless circuit structure, which forms a circuit layer on a dielectric material, such as a fan-out redistribution layer (RDL). It can be appreciated that the first carrier structure 20 can also be other types of carrier for carrying an electronic component (e.g., a chip), such as a lead frame, a silicon interposer, and the present disclosure is not so limited.

Moreover, the electronic component 21 is electrically connected to the second carrier structure 22 via the conductive bumps 210.

In an embodiment, after the conductive elements 28 and the conductive bumps 210 are reflowed and bonded to the second carrier structure 22, flux cleaning operation is performed.

As shown in FIG. 2E, an insulating layer 24 such as an underfill is formed in the gap S to cover the ends 28a of the conductive elements 28 and the conductive bumps 210. Thereafter, singulation is performed as needed.

In an embodiment, the insulating layer 24 is filled in the gap S, so that the insulating layer 24 and the covering layer 23 are arranged in the same area A.

Moreover, the thickness d of the insulating layer 24 and the height t of the conductive bumps 210 (shown in FIG. 2A) are the same.

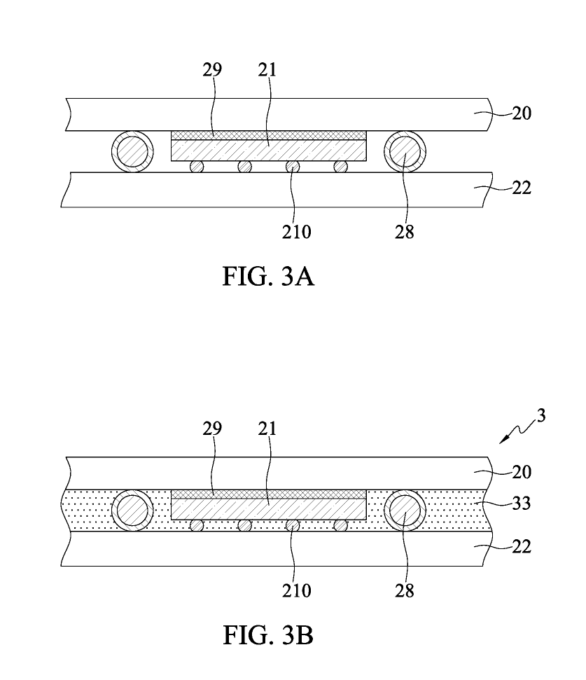

In another embodiment, a method for fabricating an electronic package 3 shown in FIGS. 3A and 3B is a continuation of the fabrication process of FIG. 2B. The first carrier structure 20 is stacked on the second carrier structure 22 via the conductive elements 28, and a covering layer 33 is formed in the remaining space between the first carrier structure 20 and the second carrier structure 22 and covers the electronic component 21, the conductive elements 28 and the conductive bumps 210, thereby omitting the step of forming the insulating layer 24 as the covering layer 33 is filled in the remaining space between the first carrier structure 20 and the second carrier structure 22.

In an embodiment, the lower face of the first carrier structure 20 is bonded and electrically connected with the electronic component 21, and the upper face of the first carrier structure 20 can be bonded to and electrically connected with at least one electronic component (not shown), wherein the electronic component can be an active element, a passive element and a combination of two. The active element can be, for example, a semiconductor chip. The passive element can be, for example, a resistor, a capacitor or an inductor.

The method for fabricating an electronic package according to the present disclosure requires only one flux cleaning operation. Therefore, compared to the prior art, the method according to the present disclosure reduces another flux cleaning procedure, thus simplifying the manufacturing process, reducing production cost and increasing yield.

In an embodiment, the electronic component 21 is bonded onto the first carrier structure 20 via the bonding layer 29, thus achieving a better support. Specifically, the distance between the first carrier structure 20 and the second carrier structure 22 can be fixed, and the height and the volume of the conductive elements 28 can be controlled. Compared to the prior art, contacts formed by the conductive elements 28 after the conductive elements 28 are reflowed according to the present disclosure are able to maintain good electrical connection, and good coplanarity of the grid array formed by the conductive elements 28 is achieved, resulting in balanced contact stress and no sloped coupling between the first and the second carrier structures 20 and 22. This prevents contact offset. Therefore, the method for fabricating an electronic package according to the present disclosure increases product yield.

In an embodiment, with the provision of the bonding layer 29, during molding of the covering layer 23, the packaging material of the covering layer 23 creates an upward push force, the bonding layer 29 can also absorb stress to reduce the stress experienced by the conductive elements 28, preventing rupture of the conductive elements 28.

Moreover, using the fabrication processes shown in FIGS. 2C to 2D, that is, forming the covering layer 23 before the stacking process, the electronic package 2 is given better support. Specifically, compared to the overall height and volume of the conductive elements 28, the height and volume of the ends 28a of the conductive elements 28 according to the present disclosure are smaller, so after reflow of the ends 28a of the conductive elements 28, the contact formed by the ends 28a of the conductive elements 28 is able to maintain good electrical connection, and good coplanarity of the grid array formed by the ends 28a of the conductive elements 28 can be achieved, resulting in balanced contact stress and no sloped coupling between the first and the second carrier structures 20 and 22. This prevents contact offset. Therefore, the fabrication method of the present disclosure increases product yield.

The present disclosure provides an electronic package 2, 3, which may include: a first carrier structure 20, an electronic component 21 provided on the first carrier structure 20 via the bonding layer 29, a first carrier structure 20 stacked on a second carrier structure 22, and a covering layer 23, 33 covering the electronic component 21.

The first carrier structure 20 is stacked on the second carrier structure 22 via a plurality of conductive elements 28.

The covering layer 23, 33 are formed between the first carrier structure 20 and the second carrier structure 22 to cover the electronic component 21 and the conductive elements 28.

In an embodiment, the electronic component 21 is electrically connected with the second carrier structure 22 via a plurality of conductive bumps 210. In another embodiment, the covering layer 33 further covers these conductive bumps 210.

In an embodiment, the bonding layer 29 is an adhesive material, a film or a heat dissipating material.

In an embodiment, the conductive elements 28 comprise metal bumps 280 and conductive materials 281 surrounding the metal bumps 280.

In an embodiment, portions of surfaces (e.g., ends 28a) of the conductive elements 28 protrude from a surface 23a of the covering layer 23.

In an embodiment, a gap S is formed between the covering layer 23 and the second carrier structure 22. In another embodiment, an insulating layer 24 is formed in the gap S to cover the ends 28a of the conductive elements 28. In yet another embodiment, the insulating layer 24 and the covering layer 23 are disposed in the same area A.

In an embodiment, the surface 23a of the covering layer 23 is flush with an active face 21a of the electronic component 21.

In conclusion, an electronic package and a method for fabricating the same according to the present disclosure achieve better support of the electronic component by providing the bonding layer on the first carrier structure. The product yield can also be increased.

Moreover, a method for fabricating an electronic package according to the present disclosure requires only one flux cleaning process, reducing the number of flux cleaning processes, thereby simplifying the manufacturing processes, reducing production cost and increasing product yield.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. An electronic package, comprising:
a first carrier structure;
an electronic component provided on the first carrier structure via a bonding layer;
a second carrier structure stacked on the first carrier structure via a plurality of conductive elements and electrically connected with the electronic component; and
a covering layer formed between the first carrier structure and the second carrier structure and covering the electronic component and the conductive elements.

2. The electronic package of claim 1, wherein the electronic component is electrically connected with the second carrier structure via conductive bumps.

3. The electronic package of claim 2, wherein the covering layer further covers the conductive bumps.

4. The electronic package of claim 1, wherein the bonding layer is made of an adhesive material, a film or a heat dissipating material.

5. The electronic package of claim 1, wherein the conductive elements include metal bumps and conductive materials covering the metal bumps.

6. The electronic package of claim 1, wherein a gap is formed between the covering layer and the second carrier structure.

7. The electronic package of claim 6, wherein portions of surfaces of the conductive elements protrude from a surface of the covering layer.

8. The electronic package of claim 7, further comprising an insulating layer formed in the gap and covering the portions of the surfaces of the conductive elements protruding from the surface of the covering layer.

9. The electronic package of claim 8, wherein the insulating layer and the covering layer are formed in the same area.

10. The electronic package of claim 6, wherein the electronic component includes an active face flush with a surface of the covering layer and a non-active face opposite to the active face and bonded to the bonding layer.

11. A method for fabricating an electronic package, comprising:
bonding an electronic component onto a first carrier structure via a bonding layer;
stacking the first carrier structure on a second carrier structure via a plurality of conductive elements, and electrically connecting the electronic component and the second carrier structure; and
forming between the first carrier structure and the second carrier structure a covering layer covering the electronic component and the conductive elements.

12. The method of claim 11, wherein the electronic component is electrically connected with the second carrier structure via conductive bumps covered by the covering layer.

13. The method of claim 11, wherein the bonding layer is made of an adhesive material, a film or a heat dissipating material, and the conductive elements include metal bumps and conductive materials covering the metal bumps.

14. The method of claim 11, wherein a gap is formed between the covering layer and the second carrier structure.

15. The method of claim 14, wherein portions of surfaces of the conductive elements protrude from a surface of the covering layer.

16. The method of claim 15, further comprising forming an insulating layer in the gap with the insulating layer covering the portions of the surfaces of the conductive elements protruding from the surface of the covering layer, wherein the insulating layer and the covering layer are formed in the same area.

17. The method of claim 14, wherein the electronic component includes an active face flush with a surface of the covering layer and a non-active face opposite to the active face and bonded to the bonding layer.

18. The method of claim 11, further comprising:
disposing the conductive elements on the first carrier structure;
forming on the first carrier structure the covering layer covering the electronic component and the conductive elements with portions of surfaces of the conductive elements being exposed from the covering layer; and
stacking the first carrier structure on the second carrier structure via the conductive elements with the covering layer formed between the first carrier structure and the second carrier structure.

19. The method of claim 11, further comprising:
disposing the conductive elements on the first carrier structure;
stacking the first carrier structure on the second carrier structure via the plurality of conductive elements; and
forming between the first carrier structure and the second carrier structure the covering layer covering the electronic component and the conductive elements.

20. The method of claim 11, further comprising performing a flux cleaning operation after stacking the first carrier structure on the second carrier structure via the plurality of conductive elements.
